(19) United States
(12) Patent Application Publication
(10) Pub. No.: US 2007/0257295 A1
(43) Pub. Date: Nov. 8, 2007

(54) Semiconductor memory device

(75) Inventors: Hiroshi Miki, Tokyo (JP); Yuichi Matsui, Kawasaki (JP)

Correspondence Address: MILES & STOCKBRIDGE PC, 1751 PINNACLE DRIVE, SUITE 500, MCLEAN, VA, 22102-3833, US

(73) Assignee: Hitachi, Ltd.

(21) Appl. No.: 11/713,591

(22) Filed: Mar. 5, 2007

(30) Foreign Application Priority Data
Mar. 29, 2006 (JP) 2006-091429

(51) Int. Cl. H01L 29/94

(52) U.S. Cl. 257/310; 257/E27.084

(57) ABSTRACT

A capacitance of a capacitor including a metal electrode is increased by using a dielectric film having a high dielectric constant. A band gap is reduced as the dielectric constant of a material is increased. In a dielectric having the dielectric constant of 50 or more such as strontium titanate, the high dielectric constant is ensured due to the crystallization but the side effect of the increased leakage current occurs. Since the replacement of the material requires the significant change of the manufacturing apparatus or the manufacturing process, the manufacturing cost is increased.

Hafnium oxide is not replaced with the other materials, but the dielectric constant of hafnium oxide is improved to increase the capacitance. An element having a large ion radius such as yttrium is added in a small amount to increase the dielectric constant of hafnium while an amorphous state is maintained. The capacitor process where the amorphous state is maintained is applied to produce the DRAM at low cost.

### CLAIM OF PRIORITY

The present application claims priority from Japanese application JP 2006-091429 filed on Mar. 29, 2006, the content of which is hereby incorporated by reference into this application.

### BACKGROUND OF THE INVENTION

1. Field of the Invention

The present invention relates to a dynamic random access memory (hereinafter, referred to as “DRAM”) and, more particularly, to a storage capacitor that constitutes a memory cell in conjunction with an MOS transistor.

2. Description of the Related Art

A memory cell of a DRAM is formed of a pair of MOS transistor and capacitor. In order to ensure high integration of the DRAM, it is required to reduce the sizes of not only the MOS transistor but also the capacitor. In respect to the reduction in size of the memory cell, a performance of the MOS transistor is improved as the length of the gate is reduced. However, in the case of the capacitor, the capacitance is reduced as the area is reduced. Meanwhile, it is necessary to ensure the capacitance per cell of about 25 fF in order to avoid data errors due to various types of noises and to maintain a predetermined refresh interval even though the size of the memory cell is reduced. Therefore, in order to reduce the size of the memory cell, there is a need to develop a process for improving a capacitance per unit area.

To satisfy the above-mentioned need, two processes may be suggested. One of the processes is the process in which the electrode included in the capacitor is three-dimensionally formed so that an effective area is not reduced even though a foot print is reduced. With respect to such process, techniques such as a stacked capacitor structure, a trench capacitor structure, and a rugged electrode were developed and have been used to produce the DRAM. The other process is the process in which the dielectric constant ε of the dielectric material constituting the capacitor is increased to improve the capacitance. In the process, aluminum oxide (ε≅9) or tantalum pentoxide (ε≅25) is used as the dielectric material instead of silicon dioxide (ε≅4).

With respect to the application of the material having the high dielectric constant in the latter process, it is noted that the surface of the electrode is slightly corroded and the interfacial layer having the low dielectric constant is formed during the manufacturing process, causing substantial reduction in dielectric constant. Particularly, in the case of the capacitor in which poly crystalline silicon is used as the electrode, the high dielectric constant is not ensured due to silicon dioxide generated at the interface.

Accordingly, in the fine memory cell that has a minimum feature size of 0.1 μm or less, the electrode is made of anti-corrosion metal instead of poly crystalline silicon that has been conventionally used. For example, Non-Patent Document 1 (IEEE International electron device meeting technical digest 2003, p. 661-664 (Technical Digest of IEDM 2003, pp. 661-664) discloses that the capacitor including the metal electrode and titanium nitride and hafnium dioxide as the material having the high dielectric constant is useful to produce the DRAM.

However, in accordance with the use of metal electrodes made of TiN, etc., the known rugged electrode process is not used any longer. The reason is as follows. The rugged electrode is produced using a hemisphere structure that is formed in the course of crystallizing amorphous silicon, and cannot be applied to materials other than silicon. Furthermore, since the rugged electrode strengthens the three-dimensional formation of the memory cell to increase the effective area, the rugged electrode has a disadvantage in views of yield. Hence, it cannot be expected to ensure the desirable three-dimensional formation of the electrode using the capacitor having the minimum feature size of 0.1 μm or less with respect to the processes that are mentioned in the section of Background Art.

Accordingly, it is required that an increase in the capacitance of the capacitor including the metal electrode is achieved almost completely by the dielectric film having the higher dielectric constant. However, the band gap is generally reduced as the dielectric constant of the material is increased. In the most of the dielectric materials having the dielectric constant of about 50 or more such as strontium titanate, the high dielectric constant is ensured after the crystallization but the side effect of the increased leakage current occurs. Furthermore, since the replacement of the dielectric material requires the significant change of the manufacturing apparatus or the manufacturing process, the manufacturing cost is inevitably increased.

### SUMMARY OF THE INVENTION

One of representative embodiments selected from the semiconductor memory devices disclosed herein is shown as follows. A semiconductor memory device according to an embodiment of the invention includes a DRAM cell including a capacitor that is formed of a lower electrode, a dielectric film, and a top electrode. The dielectric film contains hafnium oxide and yttrium oxide as main components.

Firstly, the invention will be hereinafter briefly described. In the invention, hafnium dioxide is not replaced with the other materials, but a means for improving the dielectric constant of hafnium dioxide to increase the capacitance is provided. This is on the basis of the thorough investigation by the inventors, resulting in the finding that the dielectric constant can be increased by adding a small amount of element having the large ion radius such as yttrium. In this specification, hafnium oxide to which yttrium is added is referred to as YHO. The inventors found that YHO showed the increased dielectric constant when it was either crystalline or amorphous. Particularly, it is preferable to use YHO as an amorphous material. With respect to this, the preferable addition method and addition amount of yttrium, and the deposition method to the DRAM memory cell will be described in embodiments below.

When the capacitor having the above-mentioned configuration is applied to the memory cell of the DRAM, it is possible to obtain a signal charge required to operate the fine memory cell having the minimum feature size of 0.1 μm or less. Particularly, since the capacitor of the invention can be operated with a dielectric material having the amorphous structure, it is possible to avoid the increase in leak current occurring due to the characteristic of the grain boundary.

### BRIEF DESCRIPTION OF THE DRAWINGS

FIG. 1 is a cross-sectional view of a DRAM memory cell that is provided in a semiconductor memory device according to an embodiment of the invention.

FIG. 2 is a cross-sectional view of the DRAM memory cell shown in FIG. 1 at an intermediate step of a process.

FIG. 3 is a cross-sectional view of the DRAM memory cell shown in FIG. 1 at an intermediate step of a process.

FIG. 4 is a cross-sectional view of the DRAM memory cell shown in FIG. 1 at an intermediate step of a process.

FIG. 5 is a cross-sectional view of the DRAM memory cell shown in FIG. 1 at an intermediate step of a process.

FIG. 6 is a cross-sectional view of the DRAM memory cell shown in FIG. 1 at an intermediate step of a process.

FIG. 7 is a cross-sectional view of the DRAM memory cell shown in FIG. 1 at an intermediate step of a process.

FIG. 8 is a cross-sectional view of the DRAM memory cell shown in FIG. 1 at an intermediate step of a process.

FIG. 9 is a view illustrating the relationship of an effective oxide thickness and a physical thickness of a hafnium oxide film to which yttrium is added that is included in the semiconductor memory device of the invention.

FIG. 10 is a view illustrating the TDDB evaluation results of the hafnium oxide film to which yttrium is added that is included in the semiconductor memory device of the invention.

FIG. 11 is a view illustrating the TDDB evaluation results of the hafnium oxide film to which yttrium is added that is included in the semiconductor memory device of the invention.

FIG. 12 is a cross-sectional view of a DRAM memory cell that is provided in a semiconductor memory device according to another embodiment of the invention.

### DETAILED DESCRIPTION OF THE PREFERRED EMBODIMENTS

The embodiments of the semiconductor memory device according to the invention will be described in detail with reference to the accompanying drawings.

### First Embodiment

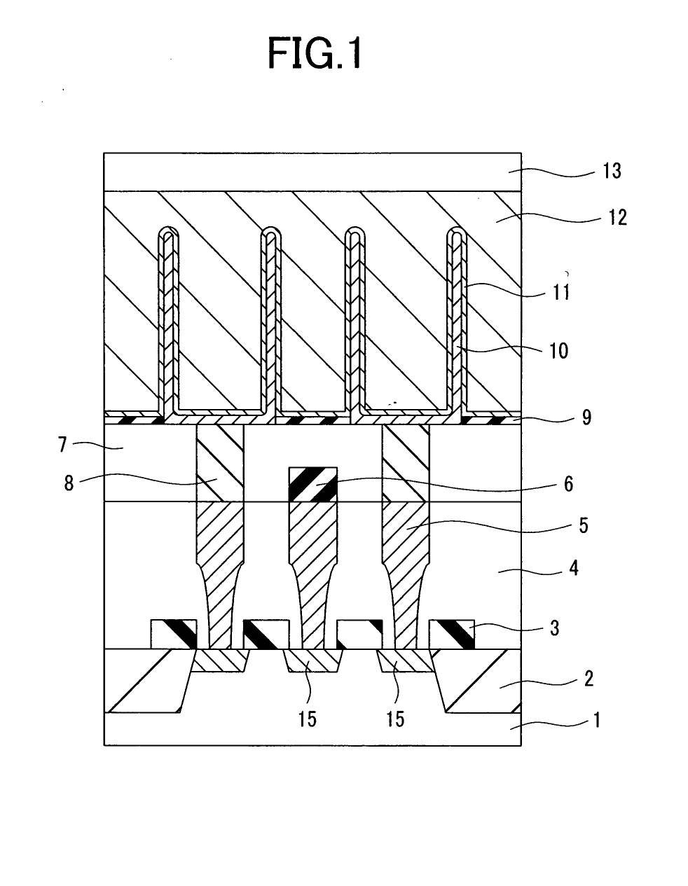

FIG. 1 is a sectional view of a semiconductor memory device, more particularly, of a DRAM, according to an embodiment of the invention. A transistor, a word line, and a bit line are formed on a silicon substrate 1 by a conventional method, and a conductive plug 5 made of polysilicon extends from a side of a diffusion layer 15 included in the transistor. A second conductive plug 8 is connected to an upper part of the resulting structure, and also connected through an etching stopper layer 9 to a capacitor lower electrode 10 having a cylinder shape.

Hafnium oxide (YHO) 11 to which yttrium oxide is added in an amount of 8% is formed on a surface of the lower electrode 10, and a top electrode 12, the lower electrode 10, and the YHO 11 constitute the capacitor.

The method of forming the DRAM cell will be described in detail hereinafter.

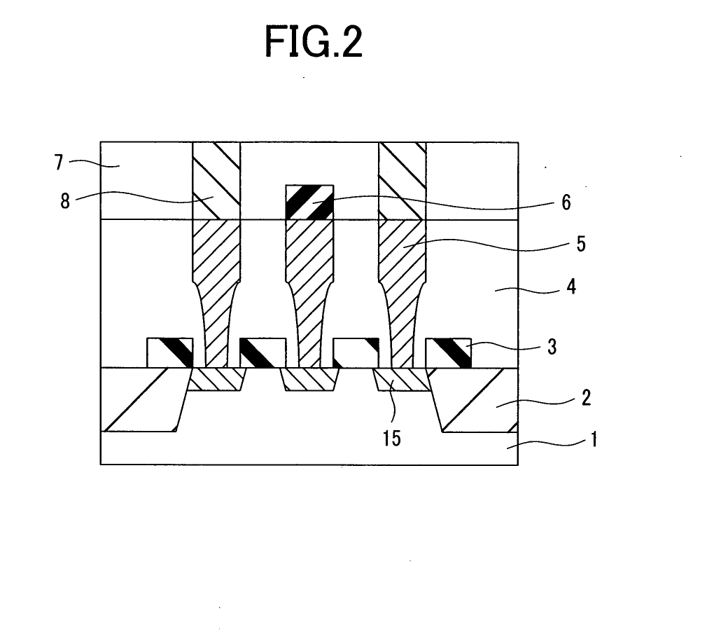

FIG. 2 is a sectional view of the memory cell in which the transistor included in the memory cell, the word line 3, the bit line 6, and wiring line plugs connecting to the capacitor lower electrode are formed. After a device isolation structure 2 and a well structure (not shown) of the transistor are formed on the silicon substrate 1, the word line 3 that has the function of the gate electrode is formed. Conductive plug 5 made of polysilicon connecting to the bit line is formed between the word lines. In connection with this embodiment shown in FIG. 2, the transistor has a known plane structure, but, in the invention, the transistor may have a recessed gate structure or a fin structure in order to control a short channel effect.

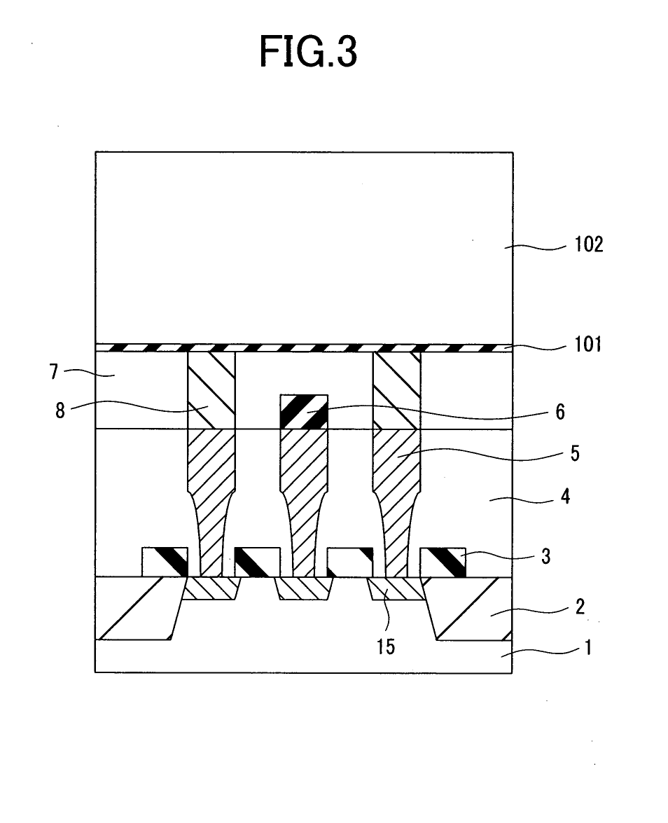

Next, an interlayer dielectric is deposited on the structure shown in FIG. 2 to determine the height of the capacitor electrode. In connection with this embodiment, a silicon nitride layer 101 and a silicon oxide layer 102 are stacked to constitute the etching stopper layer 9 shown in FIG. 1. The silicon nitride layer 101 is deposited to have a thickness of 5 to 20 nm by a CVD process (see FIG. 3). Tetraethoxy silane and oxygen are then used as precursors.

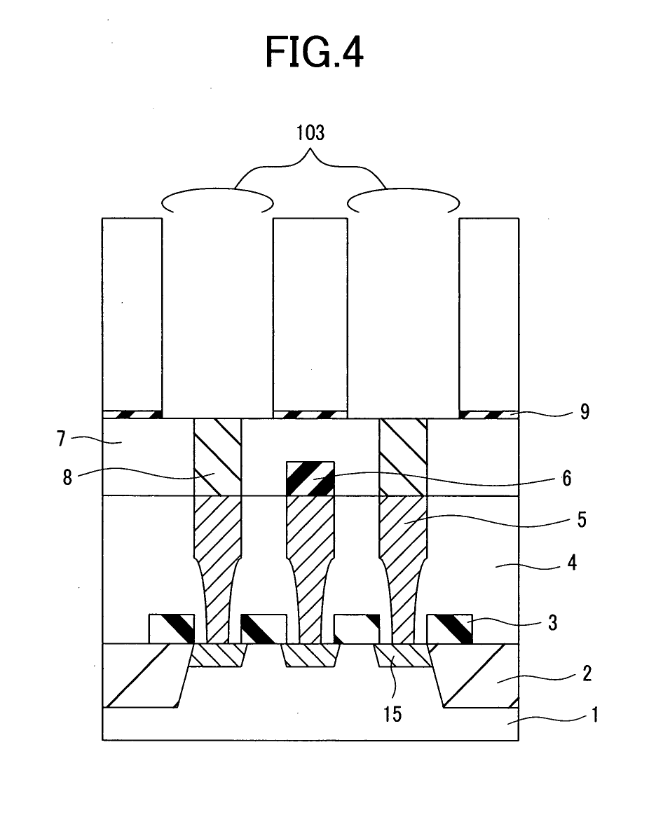

A silicon oxide layer 102 is formed to have a thickness of 1 to 3 μm by a plasma CVD process. The silicon oxide layer 102 and the silicon nitride layer 101 of a portion 103 on which the capacitor is formed are removed by a photolithography process and a dry etching process to form a structure shown in FIG. 4. FIGS. 1 to 8 arbitrarily show the layer thickness and the aspect ratio for convenience of the understanding. However, since a hole structure includes an opening that has a diameter of about 50 to 150 nm and a height of 1 to 3 μm, a ratio of the diameter to the depth for the opening (hereinafter, referred to as “aspect ratio”) is a few tens which means that the hole structure has the very deep opening.

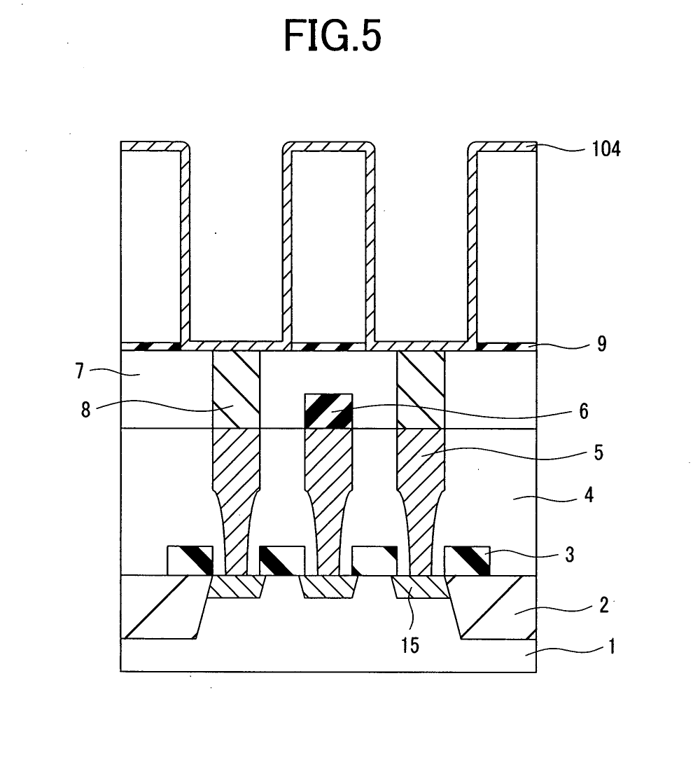

Next, titanium nitride that is to constitute the lower electrode 10 is deposited to have a thickness of 10 to 40 nm by the CVD process (see FIG. 5). The titanium nitride layer 104 can be preferably produced by means of the CVD process using ammonia and titanium tetrachloride, or is preferably made of titanium nitride by means of an atomic layer deposition (hereinafter, referred to as “ALD”) process. In the ALD process, the layer forming speed is slower in comparison with that in the CVD process. However, when it is necessary to uniformly form the layer on the internal wall or the bottom of the structure having the significantly high aspect ratio, the characteristic of the ALD process where the step coverage is excellent may be effective.

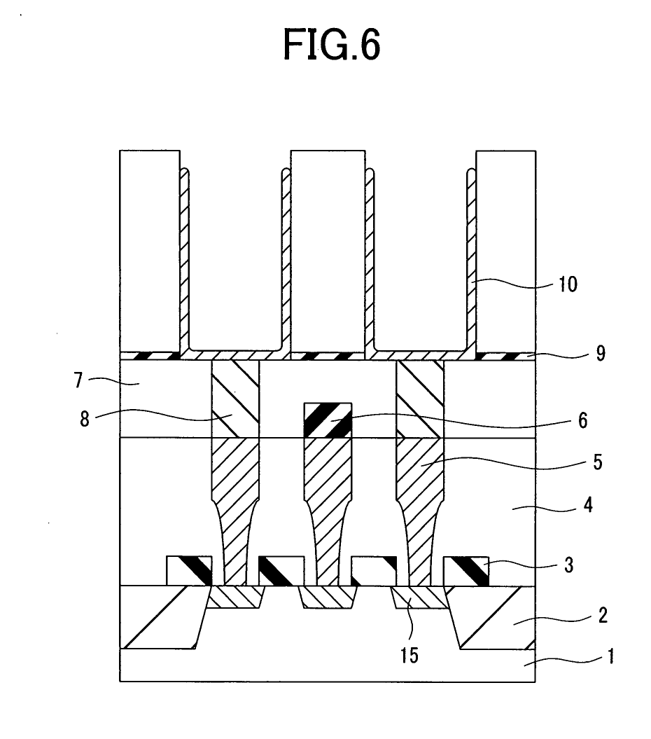

Subsequently, an etch back process is performed in order to divide the lower electrode for each bit. After a positive type photoresist is applied onto the structure shown in FIG. 5, the entire surface of the chip is exposed and developed to remove the resist on the silicon oxide layer 102, and the photoresist that is not subjected to the exposure remains in the hole structure 103. When the dry etching process is performed in respect to the structure, only the titanium nitride layer between the bits is removed to form the structure where the lower electrode 10 is divided for each bit as shown in FIG. 6.

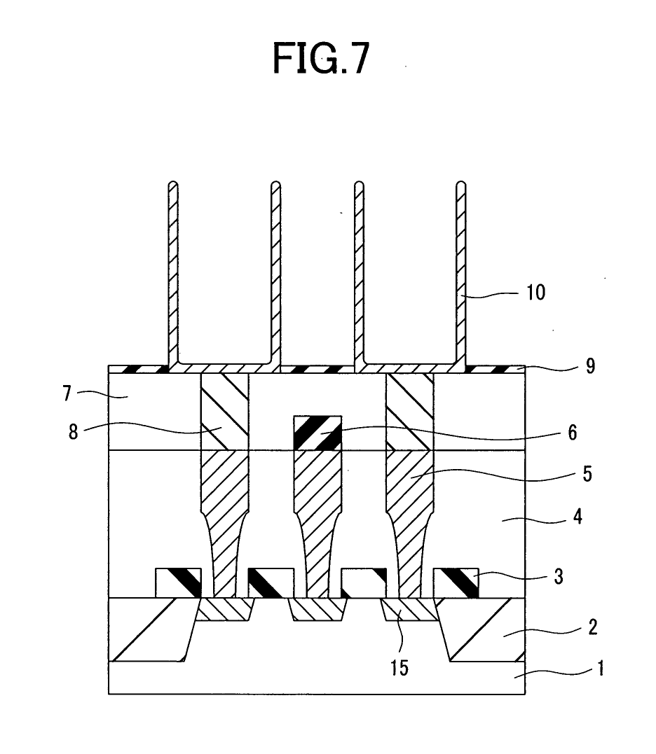

Furthermore, the silicon oxide layer 102 and the photoresist are removed by the wet etching process to form a lower electrode structure 10 where only the titanium nitride layer 104 having the cylinder shape is present (see FIG. 7). In the removing process of the photoresist, a very thin titanium oxide layer (not shown) is formed on the surface of the titanium nitride.

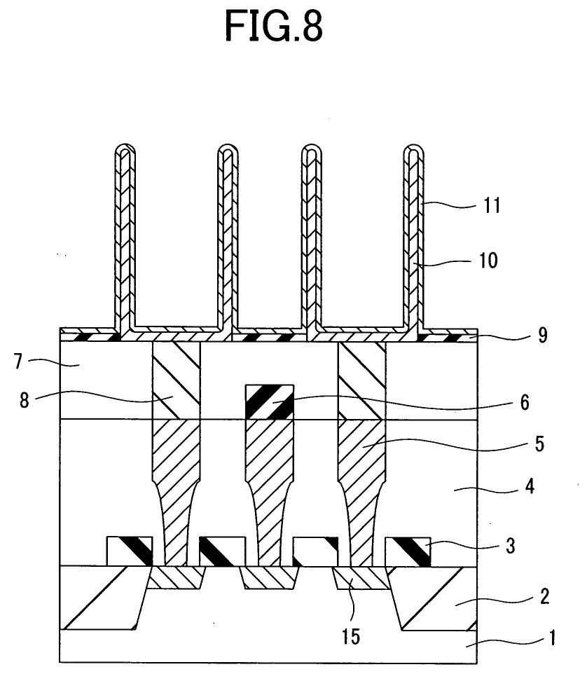

Subsequently, the YHO layer that is the main target of the invention is formed. First, the thin titanium oxide layer that is formed on the surface of the titanium nitride by the manufacturing process is removed with a buffered hydrofluoric acid. Subsequently, the hafnium oxide layer 11 to which yttrium is added in an amount of 8% is formed to have a thickness of 6 nm by means of the ALD process using a yttrium complex, a hafnium complex, and ozone (see FIG. 8). The temperature for depositing the hafnium oxide layer 11 is 250 to 350° C.

Since the deposition temperature is such low temperature, the oxidation of the surface of the titanium nitride or the crystallization of YHO may be suppressed. In particular, the low temperature is useful to the case where the addition amount of yttrium is less than about 10%.

If the addition amount of yttrium into the hafnium oxide layer 11 is small, the crystallization temperature of the hafnium oxide layer 11 is almost the same as that of hafnium oxide, and the crystallization occurs. Thus, it is difficult to maintain the amorphous state of the hafnium oxide layer 11, which is the main target of the invention. Furthermore, the addition amount of yttrium significantly affects the dielectric constant of the insulating layer in the final product. The connection of the layer formation temperature, the addition amount, the crystallization temperature, and the dielectric constant will be described in detail in a second embodiment below.

Further, a top electrode 12 is formed by means of the CVD process or the ALD process using titanium nitride. Preferably, the ALD process is used for forming the top electrode 12. The reason why the ALD process is preferably used for forming the top electrode 12 is as follows. The capacitor opening shown in FIG. 8 tapers by the titanium nitride layer and the hafnium oxide layer into which yttrium is added, and the diameter of the narrowest portion of the capacitor opening is less than 15 nm. The depth of the opening is a few μm, and a burying process in which the aspect ratio is high is performed. Meanwhile, a process for forming the top electrode at the high temperature of higher than 500° C. may undesirably cause the crystallization of the hafnium oxide layer into which yttrium is added. Accordingly, it is preferable to perform the ALD process, in which the layer is capable of being formed at low temperature and the step coverage is excellent, for forming the top electrode 12.

A tungsten layer 13 is formed on the titanium nitride layer by a sputtering process in order to reduce sheet resistance required as a plate electrode so as to produce the structure shown in FIG. 1, the titanium nitride layer being formed by the ALD process.

With respect to the capacitor opening having the diameter of 80 nm and the depth of 2 μm, an average storage capacitance of the capacitor is about 35 fF per bit in the case where hafnium oxide of 6 nm to which yttrium is added in an amount of 8% is used, and the capacitance enough to operate the DRAM memory cell can be ensured. Furthermore, when a voltage of 1 V is applied, the leak current is less than 1 fA per bit, the refresh current interval is desirably long, and the desirable yield or reliability can be ensured.

Meanwhile, it is impossible to ensure the above-mentioned advantages using pure hafnium oxide to which yttrium is not added. The two reasons why it is impossible are as follows. First, since it is necessary to form the thin film of hafnium oxide to have a thickness of about 3 nm in the case where the thin film is formed without adding yttrium into the hafnium oxide to ensure the same level of capacitance as the case yttrium is added into the hafnium oxide, the leak current of the capacitor is increased. Thus, it is impossible to operate the chip. Furthermore, in the case where the height of the capacitor is increased while the thickness of the film of hafnium oxide is 6 nm as same as the case yttrium is added into the hafnium oxide, it is required that the height of the capacitor is 3.5 μm or more to ensure the desired capacitance. The above-mentioned process is problematic in that since it is difficult to process the opening 103 shown in FIG. 4 and to ensure the mechanical stability of the lower electrode 10 shown in FIG. 7 so that a short circuit may occur between the adjacent bits. According to the invention, it is possible to avoid the above-mentioned problems and to produce the DRAM chip at desirable yield.

### Second Embodiment

In this embodiment, the dielectric characteristics and the reliability of the capacitor that is produced using hafnium oxide to which yttrium is added will be described in detail.

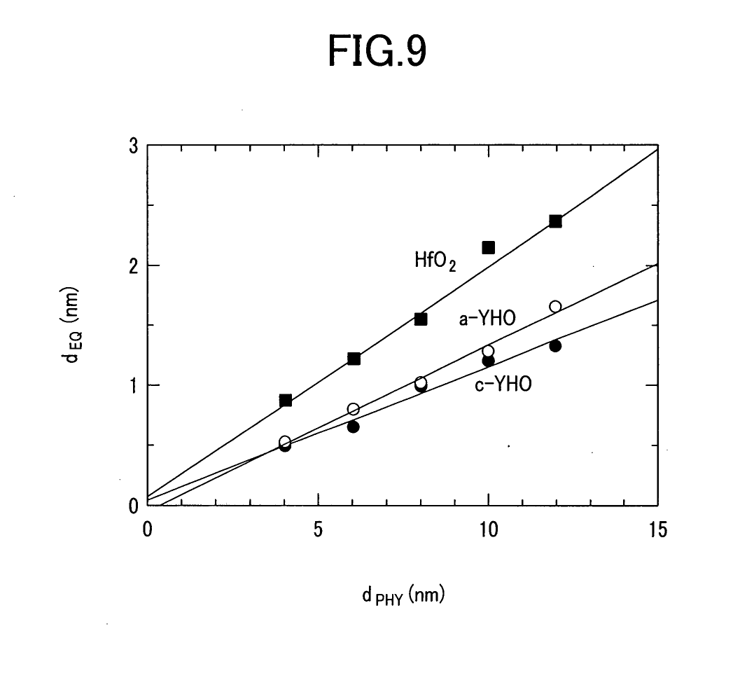

With respect to pure hafnium oxide and hafnium oxide to which yttrium is added in an amount of 8%, the relation of SiO₂ effective oxide thickness d_{EQ} and the physical thickness d_{PHY} was examined using the plane capacitor in which the lower electrode was made of titanium nitride, and the obtained results are shown in FIG. 9. Here, YHO shown in FIGS. 9 to 11 means hafnium oxide to which yttrium is added in an amount of 8%. The composition ratio of 8% means a ratio of the atomic number of yttrium to the atomic number of metal elements (hafnium+yttrium) included in the insulating film. In FIG. 9, the crystallized YHO is designated by c-YHO and the amorphous YHO is designated by a-YHO. The crystallization was performed by intentionally performing the heat treatment in an oxygen atmosphere at 600° C. after the deposition. The pure hafnium dioxide was not subjected to the heat treatment for crystallization, and had the amorphous structure.

Since the vertical axis of FIG. 9 is the SiO₂ effective oxide thickness, when the slope formed by joining points is gradual, the effective oxide thickness is not increased even though the film thickness is increased. This means that the dielectric constant is high. The slope of YHO is almost the half of the slope of the pure hafnium oxide. That is, it can be seen that the dielectric constant of YHO is about 2 times as high as that of the pure hafnium oxide. The dielectric constant is about 30 to 35.

Furthermore, it should be noted that the increase in dielectric constant is ensured without the substantial crystallization. In FIG. 9, in respect to the amorphous YHO (a-YHO) and the crystallized YHO (c-YHO), the effective oxide thickness of the crystallized YHO tends to be relatively lower in the region in which the film thickness is large. However, there is a small difference in the physical thickness region (5 nm to 10 nm) of the invention.

The reason for the above-mentioned tendency is thought that the very thin titanium oxide layer is formed on the surface of the lower electrode during the crystallization process, and it is equivalent to that the entire film thickness is increased. As described below, the thin titanium oxide layer may affect the reduction in reliability of the capacitor to no small extent.

In addition, the use of YHO as an amorphous material gives an effect to lower the lower limit of the physical thickness available in the invention. In general, it is known that in the case of the capacitor of the thin film dielectric material, if the thickness of the insulating film is about 3.5 nm or less, the direct tunneling current is observed. In the case where the crystallization occurs, the nonuniformity of the film thickness occurs due to the grain growth, and the direct tunneling current is observed in a large amount even in the thicker film. This can be minimized by using the amorphous material, and the lower limit of the thin film may be about 5 nm.

In the invention, it is considered that the formation of YHO in the DRAM memory cell without the crystallization of YHO is preferable. Thus, it was considered to perform the formation process at low temperatures. When the formation in the DRAM memory structure was performed, if the addition amount of yttrium was 8% and the film thickness was 8 nm, the temperature at which the crystallization of YHO started was estimated as about 500° C. The temperature about 500° C.” was almost the same as the temperature in the case where the pure hafnium oxide was used. In the case of the planar capacitor structure, the amorphous state of YHO was sometimes maintained at higher temperatures. However, in the case of the three-dimensional capacitor, the threshold temperature at which the crystallization started was slightly lower and was about 500° C. due to the temperature distribution or the stress caused by the structural characteristics.

Among the factors of the temperature, the temperature for the deposition process of the insulating film most significantly affected the crystallization, and the crystallization often occurred even in the deposition condition of about 450° C. From the above-mentioned test results, it can be seen that it is necessary to set the temperature for the deposition process of the insulating film so that the thin film is desirably formed and to perform the process at sufficiently low temperatures after the deposition including the deposition of the top electrode in order to form the amorphous YHO with a predetermined margin.

In order to achieve this, the ALD process is used in the invention to perform the deposition of the insulating film, and complex materials and active ozone are used as precursors to perform the ALD reaction at low temperature. Accordingly, the temperature for the ALD reaction may be reduced to 250° C. or so. After the deposition, it is necessary to suppress the heat treatment that is performed to remove the remaining impurity, and to desirably set the feeding time of ozone used to decompose the raw materials so that the impurity is removed as many as possible during the deposition process. If the treatment after the deposition is required, the ozone treatment is additionally performed at 400° C. or less, which ends the treatment after the deposition.

When the top electrode is deposited, YHO may be crystallized. As the deposition process of the top electrode, a CVD process has been conventionally performed using ammonia and titanium tetrachloride. A typical temperature for such deposition process was 600° C. or so, at which the crystallization of YHO tends to start. Therefore, it is necessary to adopt the low temperature process such as the ALD process.

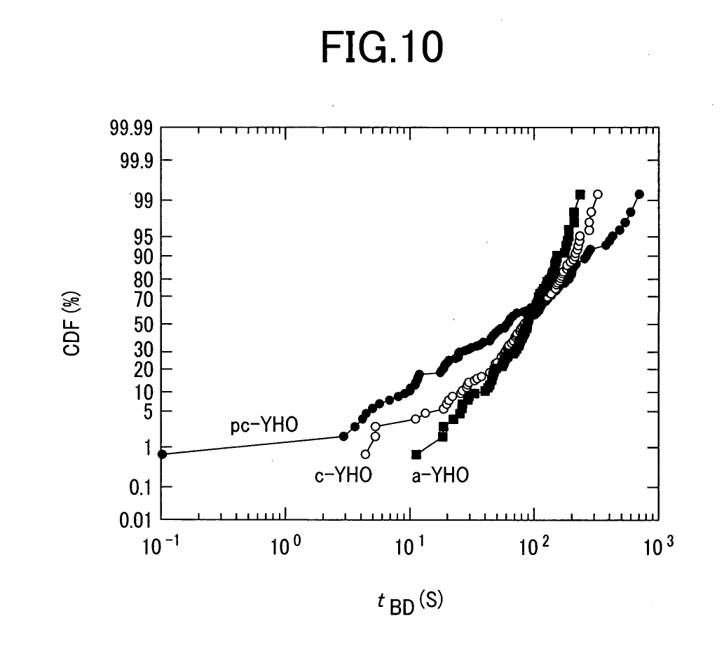

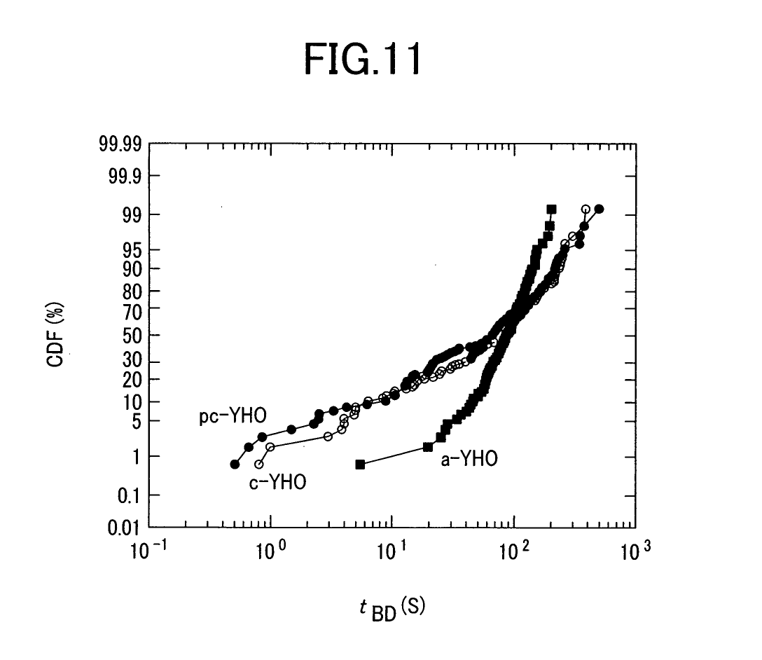

Next, the reliability of the capacitor that is formed through the above-mentioned procedure will be described. After the deposition of YHO, the following three samples were tested in views of time dependent dielectric breakdown (TDDB): the capacitor (c-YHO) in which YHO was crystallized by the heat treatment at 700° C.; the capacitor (a-YHO) in which the amorphous state of YHO was maintained by using the low temperature process; and the capacitor (pc-YHO) in which the top electrode is formed by a conventional CVD process so that the partial crystallization of YHO occurred. The obtained results are shown in FIGS. 10 and 11. Meanwhile, in FIGS. 10 and 11, CDF (%) of the vertical axis means a cumulative failure rate, and t_{BD} (S) of the horizontal axis means a breakdown time (sec). The average breakdown times of the three samples were almost the same among the three samples. However, there was a significant difference in views of distribution.

First, in the case of the film of FIG. 10 that is relatively thinner than the film of FIG. 11, the sample having the short life that deviates from the distribution with a possibility of about 1% due to the crystallization can be found. It can be understood that this result means that some of the grain boundaries generated due to the crystallization acts as a path of the leak current due to the segregation of the impurity. That is, it can be seen that the yield of the capacitor is reduced due to the crystallization, so as to significantly affect the yield of the DRAM products.

In the case of the YHO (pc-YHO) that were partially crystallized, the reduction in yield of the capacitor even more significantly affects the yield of the DRAM products, and the samples where the lifetime distribution of the capacitor is broadened and the short circuit occurs are obtained. The reason for this result can be thought that since chlorine (obtained from titanium tetrachloride) or reduction gas (ammonia) is contained in a CVD atmosphere when the top electrode is formed by the conventional CVD process, the speed of the deterioration of the grain boundary is further increased.

The above-mentioned phenomenon was shown in the case of FIG. 11 in which YHO was intentionally made thick (about 15 nm), but there was a slight difference from the above-mentioned case. A difference between the crystallization and the partial crystallization is reduced, but a difference between the crystallized and the amorphous state is increased. Thus, it can be thought that the crystallization increases prominences and depressions at the grain boundary and the insulating film as the thickness of the film is increased.

From the TDDB evaluation results with regard to the two kind of film thicknesses, it can be seen that it is necessary to perform the cell manufacturing process where the partial crystallization of YHO is avoided in order to form YHO of the invention with high reliability.

Meanwhile, an ozone feeding step time required to remove the impurity may not be sufficiently ensured due to the limited throughput in the formation of YHO. In such case, it is more preferable to perform the intentional crystallization before the top electrode is deposited in comparison with the performing of the incomplete crystallization (see FIG. 10). In connection with this, the patterned film should not be completely crystallized after the deposition, but it is preferable to perform the two-step crystallization process in which a first crystallization is performed at the stage where the film is made as thin as possible and a second crystallization is performed after the deposition is additionally performed. From the comparison of FIGS. 10 and 11, it can be seen that the disadvantages occurring in the case of the crystallization are increased as the thickness of the film is increased.

### Third Embodiment

In this embodiment, metal ruthenium is used as the electrode. Ruthenium is advantageous in that the work function is high and the leakage current of the capacitor is lower than titanium nitride. Meanwhile, in comparison with titanium nitride, the reactivity of ruthenium to silicon is higher so that the structure in which the electrode made of ruthenium comes into contact with polysilicon is not suitable.

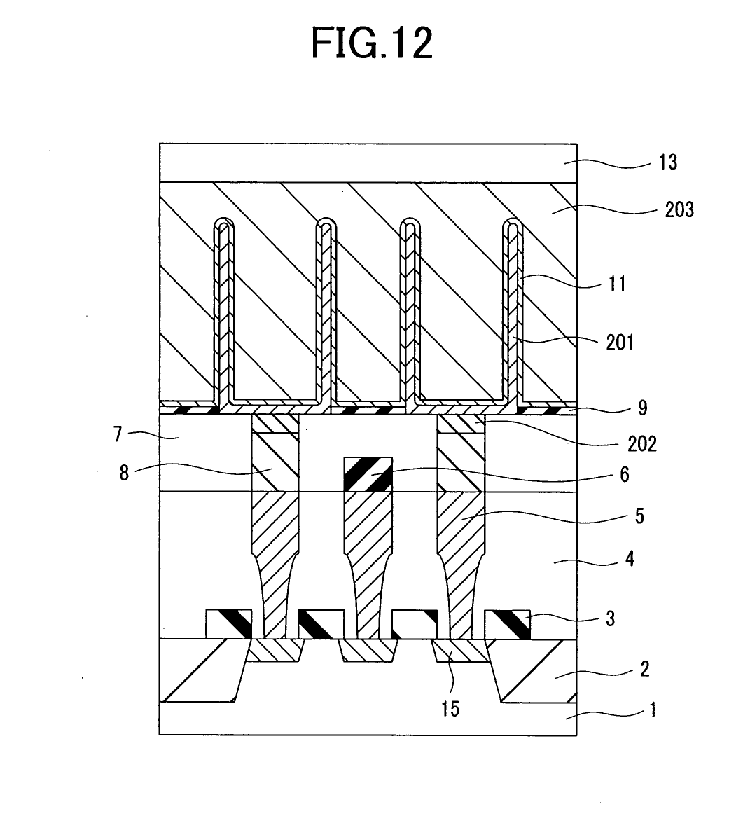

For this reason, as shown in FIG. 12, it is known that it is necessary to provide a barrier layer 202 at a portion in which a lower electrode 201 comes into contact with polysilicon 8. The barrier layer may be made of a known barrier metal such as tantalum nitride, in addition to titanium nitride. However, since the conventional barrier structure has heat resistance of about 600° C., the margin is small and it is difficult to ensure the desirable yield during the process using the material such as tantalum pentoxide having the dielectric constant of more than 30. Accordingly, the DRAM that includes the material having the high dielectric constant and ruthenium combined with each other has not been produced.

Meanwhile, YHO of the invention is advantageous in that the dielectric constant is high even in the amorphous state so that it is possible to form the structure including the lower electrode 201 made of metal ruthenium with a desirable margin. YHO of the invention may be formed at the very low temperature of 300° C. or less, and there is the margin of 300° C. or more in respect to the heat resistance of the lower electrode. The heat treatment process to remove the impurity may be performed at the low temperature of, e.g. 400° C.

Like the lower electrode 201, the top electrode 203 may be made of ruthenium. As described in the first embodiment, since a demand for step coverage is severe in respect to the top electrode 203, the tope electrode 203 should be formed by the ALD process.

In comparison with the case of the titanium nitride electrode, if the ruthenium is used as the electrode, even though the thin film is formed to have the physical thickness of about 20%, an increase in direct tunneling current can be suppressed in a low electric field.

### DESCRIPTION OF REFERENCE NUMERALS

1: Substrate
2: Device isolation oxide film
3: Word line
4: Interlayer dielectric
5: Conductive plug
6: Bit line
7: Interlayer dielectric
8: Conductive plug
9: Etching stopper layer (titanium nitride layer)
10: Lower electrode (titanium nitride)
11: Hafnium oxide to which yttrium is added
12: Top electrode (titanium nitride)
13: Plate electrode (tungsten)
15: Diffusion layer
101: Silicon nitride layer
102: Silicon oxide layer
103: Capacitor opening
104: Titanium nitride film
201: Lower electrode (ruthenium)
202: Barrier layer (titanium nitride)
203: Top electrode (Ruthenium)

1. A semiconductor memory device comprising:
a DRAM cell including a capacitor that is made up of a lower electrode, a dielectric film, and a top electrode,
wherein the dielectric film contains hafnium oxide and yttrium oxide as main components.

2. The semiconductor memory device according to claim 1, wherein the dielectric film is an amorphous film.

3. The semiconductor memory device according to claim 1, wherein at least one of the lower electrode and the top electrode is made of titanium nitride.

4. The semiconductor memory device according to claim 1, wherein at least one of the lower electrode and the top electrode is made of ruthenium.

5. The semiconductor memory device according to claim 1, wherein the dielectric film is formed by an atomic layer deposition process.

6. The semiconductor memory device according to claim 3, wherein at least one of the lower electrode and the top electrode is formed by an atomic layer deposition process.

7. The semiconductor memory device according to claim 4, wherein at least one of the lower electrode and the top electrode is formed by an atomic layer deposition process.

8. (canceled)
